(19) United States
(12) Patent Application Publication
(10) Pub. No.: US 2006/0065387 A1
(43) Pub. Date: Mar. 30, 2006

(54) Electronic assemblies and methods of making the same

(75) Inventors: Sandeep Shrikant Tonapi, Niskayuna, NY (US); Arun Virupaksha Gowda, Schenectady, NY (US); Kevin Matthew Durocher, Waterford, NY (US); David Esler, Mayfield, NY (US); Hong Zhong, Schenectady, NY (US); Ananth Prabhakumar, Schenectady, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 10/950,554

(22) Filed: Sep. 28, 2004

(51) Int. Cl. H05K 7/20

(52) U.S. Cl. 165/185; 361/704

(57) ABSTRACT

An electronic assembly having at least a heat dissipating unit and a heat generating unit is provided. At least one of the heat dissipating unit and the heat generating unit has at least one deliberately modified surface.

### STATEMENT REGARDING FEDERALLY SPONSORED RESEARCH OR DEVELOPMENT

The U.S. Government may have certain rights in this invention pursuant to contract number 70-NANB2H-3034 awarded by the U.S. National Institute of Standards and Technology.

### FIELD OF THE INVENTION

This invention relates to electronic assemblies and preparing such assemblies. More particularly, the invention relates to the reduction of thermal resistance in electronic assemblies.

### BACKGROUND OF THE INVENTION

Many electrical components generate heat during periods of operation. As electronic devices become denser and more highly integrated, the heat flux increases exponentially. At the same time, because of performance and reliability considerations, the devices need to operate at lower temperatures, thus reducing the temperature difference between the heat generating part of the device and the ambient temperature, which decreases the thermodynamic driving force for heat removal. The increased heat flux and reduced thermodynamic driving force thus require increasingly sophisticated thermal management techniques to facilitate heat removal during periods of operation.

Thermal management techniques often involve the use of some form of heat dissipating unit (which includes, but is not limited to, heat spreader, heat sink, lid, heat pipe, or any other designs and constructions known to those skilled in the art) to conduct heat away from high temperature areas in an electrical system. A heat dissipating unit is a structure formed from a high thermal conductivity material (e.g., copper, aluminum, silicon carbide, metal alloys, polymer composites and ceramic composites) that is mechanically coupled to a heat generating unit to aid in heat removal. In a relatively simple form, a dissipating unit can include a piece of metal (e.g., aluminum or copper) that is in contact with the heat generating unit. Heat from the heat generating unit flows into the heat dissipating unit through the mechanical interface between the units.

In a typical electronic package, a heat dissipating unit is mechanically coupled to the heat producing component during operation by positioning a flat surface of the heat dissipating unit against a flat surface of the heat generating component and holding the heat dissipating unit in place using some form of adhesive or fastener. As can be appreciated, the surface of the heat dissipating unit and the surface of the heat generating component will rarely be perfectly planar or smooth, so air gaps will generally exist between the surfaces. As is generally well known, the existence of air gaps between two opposing surfaces reduces the ability to transfer heat through the interface between the surfaces. Thus, these air gaps reduce the effectiveness and value of the heat dissipating unit as a thermal management device. To address this problem, polymeric compositions have been developed for placement between the heat transfer surfaces to decrease the thermal resistance therebetween.

In general, a heat dissipating unit is attached to the heat generating component via a thin-layer of thermal interface material (TIM). This material is typically a filled polymer system. The effectiveness of heat removal from the device depends on the in-situ thermal resistance of the TIM material which, in turn, depends not only on the bulk thermal conductivities of the TIM material, but also the attainable bond line thickness under industrially relevant pressure and the interfacial resistance. The minimum thickness of the TIM is determined by the degree of surface planarity and roughness of both the heat generating and the heat dissipating units, or the maximum (agglomerated) filler size, whichever is larger. However, this minimum bondline may not be always attainable, especially with highly viscous and thixotropic formulations, under industrially relevant pressure, typically below 250 psi, and more typically at or below 100 psi. In addition, a formulation's viscosity, wettability to the surface, film forming capability and storage stability can greatly affect interfacial resistance and thus the thermal interface material's in-device heat transfer capability.

In many TIM applications the TIM must be sufficiently compliant to provide mechanical isolation of the heat generating component and the heat dissipating unit in those cases where the Coefficient of Thermal Expansion (CTE) of the heat generating component is significantly different (higher or lower) than that of the heat dissipating unit. In such applications, TIM materials have to not only provide an efficient heat transfer pathway but also maintain structural integrity for the whole package or device. They have therefore to maintain satisfactory mechanical as well as thermal properties throughout the lifetime of the device.

A need therefore exists for improvements in the transfer of heat between a heat dissipating unit and a heat producing or generating unit while maintaining mechanical integrity throughout the device lifetime.

### SUMMARY OF THE INVENTION

In one embodiment of the present invention, a thermal resistance network has at least one heat dissipating unit, a die or any other heat generating unit, and at least one thermal interface material located between the heat dissipating unit and the die, wherein at least one of the heat dissipating unit and die has a deliberately modified surface.

In yet another embodiment of the present invention, a thermal resistance network has a heat dissipating unit having at least one deliberately modified surface, a heat generating unit having at least one deliberately modified surface and a thermal interface material deposited between the heat dissipating unit and said heat generating unit.

In a further embodiment of the present invention, a thermal resistance network has a heat sink, a heat spreader having a first side and a second side, a die having a first side and a second side, a first thermal interface material located adjacent said second side of said heat spreader and said first side of said die, and a second thermal interface material located adjacent said first side of said heat spreader and said heat sink, wherein at least one of said first side of heat spreader, said second side of said heat spreader, and said first side of said die has a deliberately modified surface.

In an additional embodiment, a method is provided, for forming a thermal resistance network, of the following steps: providing a heat sink; providing a heat spreader; providing a die; modifying at least one surface of at least one of said heat spreader and said die; and providing at least one thermal interface material between said heat spreader and said die.

In an additional embodiment, a semiconductor device is provided, comprising at least one heat dissipating unit, a die, at least one thermal interface material, and a circuit, wherein at least one the heat spreader and the die has a deliberately modified surface.

These and other aspects, advantages, and salient features of the present invention will become apparent from the following detailed description, the accompanying drawings, and the appended claims.

### BRIEF DESCRIPTION OF THE DRAWINGS

FIG. 1 is a cross sectional schematic view of an electronic assembly component;

FIG. 2 is a cross sectional schematic view of an electronic component having a thermal interfacial material disposed between a heat dissipating unit and a die;

FIG. 3 is a cross sectional schematic view of an electronic assembly having a heat dissipating unit with one mechanically altered side.

FIG. 4 is a cross sectional schematic view of an electronic component having a heat dissipating unit with a metal layer on one side.

FIGS. 5a and 5b are planar views of a heat dissipating unit, 5a showing a mechanically altered side and 5b showing a unit altered by laser technology.

### DETAILED DESCRIPTION OF THE INVENTION

For the sake of ease of describing the invention, a flip chip electronic assembly will be described throughout and the term “flip chip” will be used throughout this specification. The present invention is not intended to be limited to flip chip electronic assemblies and may further encompass additional types of electronic assemblies. Additionally, the terms “heat spreader” and “die” are used as examples of a heat dissipating unit and heat generating units, respectfully; however, the current invention is not intended to be limited to these specific embodiments of a heat spreader and die. Further, drawings are not to scale.

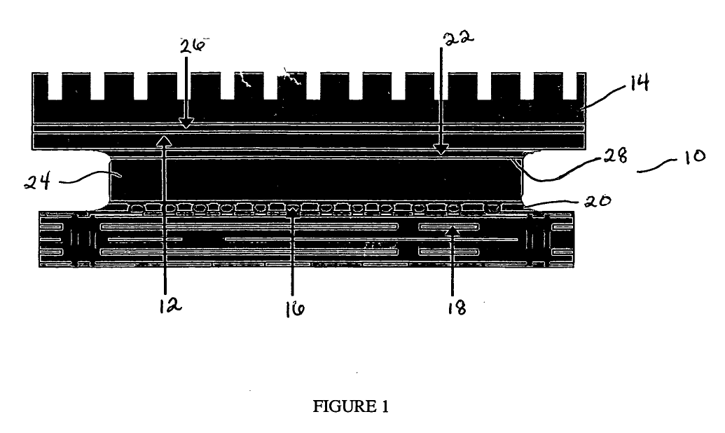

The electronic assembly of the present disclosure is a deliberately modified electronic assembly. The electronic assembly may be of any type, such as a flip chip assembly, as shown in FIG. 1, or a wire bonded surface mount device assembly, or a tape automated bonded device assembly, or any other electronic assembly known in the art. As is known in the art, components of an electronic assembly may include among other components one or more heat dissipating unit, a heat generating unit, circuitry, thermal adhesives, and interconnecting materials such as but not limited to, solder and electrically conducting adhesives. Examples of a heat dissipating unit include a heat spreader, heat sink, heat slug, cold plate, or heat pipe. The heat dissipating unit is typically in direct or indirect contact with the semiconductor device or die, the heat generating unit. A TIM may be interposed between the heat dissipating unit and the heat generating unit to fill any air gaps and facilitate heat transfer. Application of the TIM may be achieved by any method known in the art. Conventional methods include screen printing, stencil printing, syringe dispensing, pick-and-place equipment and pre-application to either the heat generating or heat dissipating unit.

The heat dissipating unit is typically made of a thermally conductive, electrically conductive, or both, material such as, but not limited to metals, ceramics, refractory materials such as refractory oxides, suicides, nitrides and carbides and composite materials, or any combination of these materials. Preferably, the heat dissipating unit is made of a metal, such as, but not limited to, gold, aluminum, copper, nickel, and alloys and combinations thereof, or silicon, or any combination of a silicon and metal combination. For example, heat spreader may employ an aluminum silicon carbide composite. Preferably, the heat dissipating unit is made of an aluminum alloy or copper alloy. The die is preferably made of a semiconductor material, such as, silicon.

In one embodiment of the present invention, a heat dissipating unit has at least one deliberately modified side. In another embodiment, the heat generating unit, or die has at least one deliberately modified surface. In yet another embodiment, both the heat dissipating unit and the die or semiconductor device will have at least one deliberately modified surface. In yet another embodiment, the electronic assembly may have two or more heat dissipating units with one or more having at least one deliberately modified surface. By deliberately modified, is meant any modification to the heat dissipating unit by intentional means such as by engineering or tailoring. Modification may occur by any mechanical, chemical or electrical means known in the art for modification of metal, ceramic, alloys, composites, or the like, surfaces. Preferably, the deliberate modification occurs by the addition of adhesion layers, mechanical roughening, surface etching, surface cleaning, or patterning. While not intending to be limiting, it is thought that the deliberate modification of the surface reduces or eliminates interfacial resistance. In each instance, deliberate modification of the surface may occur on the heat dissipating unit, the heat generating unit, or both.

Mechanical methods, or means, for deliberate modification include, but are not limited to, addition of adhesion layers, application of adhesion promoters, mechanical roughening, patterning, and combinations thereof. In one embodiment, the addition of adhesion layers enables better heat flow by addressing the interface properties such as, cracks, and voids.

Further, the addition of adhesion layers is provided by methods, such as, metal sputtering, and metal electroplating. Usually, metal sputtering employs targets, which are placed in an enclosed space having an inert gas, such as argon. Upon start of the reaction, atoms of the inert gas slam the target. Due to the collision, there is an exchange of momentum between the atoms of the target and the atoms of the inert gas. In the process, a target atom is ejected from the target and heads to the heat spreader surface and sticks on the heat spreader. In one embodiment, metal sputtering employs metal targets, such as, but not limited to titanium, molybdenum, tungsten, copper, aluminum, and combinations thereof. In a specific embodiment, a metal layer having a thickness of about 3000 Å is deposited on at least one side of the heat spreader. Metal sputtering may also be employed to modify at least one side of the die.

In another embodiment, metal electroplating is employed to deliberately modify at least one side of the heat spreader. Electroplating may also be employed to modify at least one side of the die. Metals such as copper, nickel, gold, silver and alloys and combinations thereof are employed for electroplating. In one embodiment, the heat spreader acts as the cathode and is connected to an anode by means of an electrical circuit. The cathode and anode are then placed in a conducting solution. Subsequently, on passage of current, metal is deposited on the cathode.

In yet another embodiment, a deliberately modified surface is obtained by application of at least one adhesion promoter. In general, the chemical groups are attached to the surface under modification, resulting in enhanced surface energy of the surface under modification. Typically, the adhesion promoter facilitates adhesion and also enhances the heat transfer capability of the surface. In one embodiment, adhesion promoters are alkoxysilanes. In one embodiment, the adhesion promoters of the structure RₓSi(OR′)₄-ₓ are employed, wherein R is an epoxy, acrylate, amine, vinyl, hydride, alkyl, alkenyl, phenyl, siloxyl, silyl and the like; R′ is a methyl, ethyl, hydrogen, and the like; x is an integer from 0 to 3; a mixed (OR′) is also allowed, for example, a compound such as Si(OMe)₂(OEt)₂ or Si(OMe)(OEt)₃, PhSi(OMe)₂(OH) or PhSi(OH)₂(OMe) may also be used for the practice described in the application. Alternatively, titanates may also be used. In yet another embodiment, Si(OR″)₄ or Ti(OR″)₄ is employed as the adhesion promoter, wherein R″ is methyl, ethyl, propyl, higher carbon number monovalent hydrocarbon radicals and the like.

In still another embodiment, the deliberately modified surface is accomplished by mechanical roughening, which results in improved wetting and hence better contacts at the interface. Processes such as grinding, bead blast, and the like may also be used as a mechanical roughening process for deliberate modification of a surface. Additional mechanical roughening processes as known by any one of ordinary skill in the art may be further employed.

In still another embodiment, at least one surface is subjected to patterning through processes such as milling, stamping, laser patterning, and the like. In one embodiment, laser patterning is accomplished using a UV laser (355 nm). Laser patterning leads to ablation of metal, creating trenches, which results in increased bonding area and decreased thermal resistance. Process parameters, such as, power, bite size, and focus setting, affect the cut quality and shape of the trenches. By adjusting these parameters, the depth of the trench, the profile of the cut, and the reflow or melt of the ablated surfaces may be controlled.

Chemical methods, such as, surface etching and reactive ion etch (RIE), among others known in the art, may be employed to obtain a deliberately modified surface. Surface etching may be employed with chemical reagents used to etch the surface such as but not limited to, hydrochloric acid, nitric acid, sulfuric acid, phosphoric acid, TFT, ferric chloride, and the like. TFT is a hydrogen fluoride based titanium etchant, available as UN1790 from Transene Co., Danver Mass. RIE can be used on surfaces such as, aluminum, copper, silicon, and the like to remove residual organic materials, remove native oxides and to impart ion bombardment. For RIE, an Anelva parallel plate etch system, consisting of a powered bottom electrode and a quartz electrode cover may be used. A process of utilizing oxygen and argon is used to treat the samples, and power, pressure and etch time are each controlled parameters, as is known in the art. Argon is typically incorporated into the etch chemistry, which increases the ion bombardment and results in more aggressive etching.

Each figure shown herein is representative and the present invention is not limited to the embodiments presented in the figures. For example, a flip chip electronic assembly 10 is shown in FIG. 1 with a heat spreader 12 and a heat sink 14 attached for thermal management. The flip chip is assembled onto a substrate 18 through the use of solder interconnections 16 and underfilled using an encapsulant 20. In this embodiment, the substrate 18 is a printed circuit board. A TIM 22 is also shown, applied to one side (the backside) 28 of a die 24. A heat spreader 12 is placed onto the backside 28 of the die 24 and the entire system is then cured. A TIM 26 attaches the heat sink 14 to the heat spreader 12. The TIM 26 may be the same TIM 22 as used between the die 24 and the heat spreader 12, or may be a different TIM altogether.

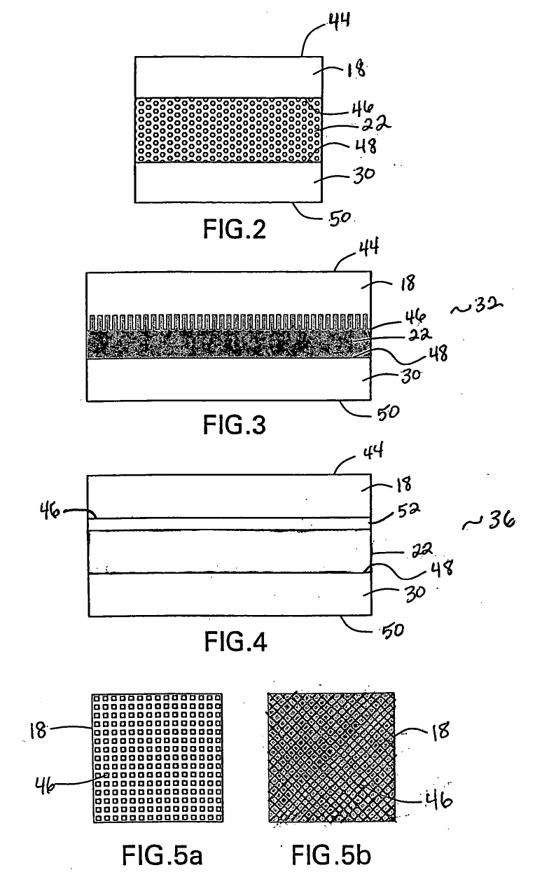

FIG. 2 is a schematic cross sectional view of a TIM 22 disposed between the heat spreader 18 and the die 30. The heat spreader 18 is made of an aluminum alloy. The die 30 is made of silicon. The heat spreader 18 has a first side 44 and a second side 46, wherein the second side 46 is in contact (interfaces) with the TIM 22. Further, the die 30 has a first side 48 and a second side 50. The TIM 22 is disposed over the first side 48 of the die 30.

The modification of least one of the first side 44 of the heat spreader 18, the second side 46 of the heat spreader 18, the first side 48 of the die, and the second side 50 of the die 30 reduces the thermal resistance of the total system. While not intending to be bound by theory, it is thought that the total system thermal resistances is reduced due to reduced interfacial resistances and better wetting and flow that result in lower bondline thickness. In one aspect of the invention, at least one of the first side 44 of the heat spreader 18, the second side 46 of the heat spreader 18, the first side 48 of the die 30, and the second side 50 of the die is modified by either mechanical or chemical means or both.

As shown in FIGS. 5a and 5b, the surface of the modified heat dissipating unit 18 changes the surface topography. FIG. 5a represents the surface 46 of a heat dissipating unit 18 after modification by patterning. FIG. 5b represents the surface 46 of a heat dissipating unit 18 after modification by laser processing. Both modifications shown in FIGS. 5a and 5b can be accomplished by laser patterning.

FIG. 3 is a schematic cross sectional view of an electronic assembly 32 having a heat sink 18 as a heat dissipating unit, having a first side 44 and a second side 46. The heat sink 18 has been mechanically modified by roughening of one side 46. The roughened side 46 is adjacent the TIM 22 which is located between the heat sink 18 and die 30. The die also has a first side 48 and a second side 50.

FIG. 4 is a schematic cross sectional view of an electronic assembly 36 having a heat sink 18 with a deliberately modified surface 46 obtained by metal sputtering. The second surface 44 is not modified. The metal sputtering deposited a layer of titanium 52. A die 30 is also present, having no deliberately modified surfaces 48 and 50. A TIM 22 is deposited between the deliberately modified surface 46 of the heat sink 18 and the die 30.

In another aspect of the invention, a method is provided to form a thermal resistance network comprising at least one heat dissipating unit, at least one heat generating unit, and a TIM. In one embodiment, the method includes the step of providing a heat dissipating unit having at least one deliberately modified surface, providing a heat generating unit having at least one deliberately modified surface, and disposing a TIM between the heat dissipating unit and heat generating unit. In yet another embodiment, only one of the heat generating unit and heat dissipating unit has a deliberately modified surface. More specifically, a heat dissipating unit, such as a heat spreader or heat sink is provided. At least one surface of the heat spreader or heat sink is deliberately modified by means described herein, including but not limited to mechanical and chemical means. A die is also provided. A TIM is then disposed on one side, or surface of the die. The heat spreader or heat sink is then placed adjacent the TIM, opposite of the die. The deliberately modified surface of the heat spreader or heat sink is preferably placed adjacent to the TIM. The TIM may be of any material such as for example, an adhesive, gel, grease, film, pad, and the like and adhered with any process known to one skilled in the art. Following coupling, the assembly is then cured, if required. In general, curing is not required for grease, pad or film TIM. The TIM, if a grease, pad or film, is typically applied to the backside of the heat generating device and the heat spreader or sink is then assembled thereon. Typically, external support in the form of clips or fixtures is required to maintain the TIM under a load and to provide structural support to the heat sink assembly. In the case of an adhesive or gel TIM, the TIM is typically a paste and is applied to the backside of the die and the heat spreader is placed thereon. The entire assembly is then cured at elevated temperatures for a period of time, typically in the range of about 100° C. to about 175° C. for about 15 minutes to about 2 hours, as is required for the various types of adhesives known in the art. The curing may occur with or without the use of a load. All examples contained herein were conducted for 2 hours at 150° C. with no external load.

In yet another aspect of the invention, a semiconductor device is provided made by the method described herein and having at least one heat dissipating unit and at least one heat generating unit, wherein at least one of the heat dissipating unit and the heat generating unit has a deliberately modified surface, and a TIM coupled between the heat generating unit and the heat dissipating unit.

The following examples are set forth to provide those of ordinary skill in the art with a detailed description of how the methods claimed herein are one aspect of the present invention may be carried out and evaluated, and are not intended to limit the scope of what the inventors regard as their invention.

### EXAMPLES

For each of the examples to follow, the thermal resistance of the interfaces formed in the heat spreader-TIM-die assembly was measured using laser flash diffusivity method (based on ASTM E-1461). The laser flash diffusivity method was used to measure the in situ and the effective thermal resistance of an electronic assembly having a heat spreader, adhesive TIM, and die. (“Measurements of Adhesive Bondline Effective Thermal Conductivity and Thermal Resistance Using the Laser Flash Method”, Campbell, Robert C, Smith, Stephen E. and Dietz, Raymond L., 15^{th} IEEE Semi-Therm Symposium, 1999, 83-97).

A laser flash instrument (Netzsch Instruments, Microflash 300) was used for the measurement of in-situ thermal conductivity and thermal resistance. A software macro that was provided with the Microflash™ instrument was used to determine the thermal conductivity and thermal resistance of the TIM. The thermal resistance of the TIM layer that was determined using this method includes the bulk thermal resistance of the TIM and the interface thermal resistance at the heat spreader-TIM, and TIM-die interfaces.

Sample preparation for the thermal resistance measurement included disposing a TIM material between two 8 mm×8 mm substrates, commonly known as coupons. These coupons are representative of a heat spreader and die. At least one of these coupons had deliberately modified surfaces and the TIM was disposed such that the deliberately modified surface of the coupon was in contact with the TIM. Coupons made of silicon, aluminum, and copper was used. Pressure of about 10 psi was applied to make the electronic assembly. The assembly was subjected to the curing conditions of 150° C. for 2 hours to obtain a cured sample. After curing, the thickness of each coupon was measured at five different locations. The original thickness of the coupons was subtracted from the total thickness of the cured assembly to obtain the Bondline Thickness (BLT) of the TIM. These assemblies were then coated with a thin layer of graphite before placing them in a laser flash diffusivity instrument.

### Example 1

One side of a heat spreader was modified by metal sputtering. Heat spreaders made of aluminum and copper were used for this example. A TIM made of silicone was employed in the assembly. Prior to metal sputtering, radio frequency (RF) sputtering was performed on the second side of the heat spreader using a Perkin Elmer vertical sputtering system. RF sputtering was done to remove any impurities, such as organic films or oxide layers from the surface of the heat spreader. A Perkin Elmer vertical sputtering tool was also employed to sputter the metal on the second side of the heat spreader. Targets made of aluminum, titanium, copper, molybdenum, and titanium-tungsten were used. Targets of a triangular shape, with a size of about 9 inches, and a purity of 99.995% were obtained from Williams Advanced Materials. Table 1 gives the thermal resistance of the interface between the TIM and heat spreader, before the modification of the one side of the heat spreader, and the percentage reduction in the thermal resistance after the modification of the one side of the heat spreader.

TABLE 1

| Heat | | Thermal | Reduction | |
|---|---|---|---|---|
| Spreader | Processing | Resistance | in Thermal | |
| Material | Material | (mm²K/W) | Resistance | BLT (mils) |
| Aluminum | Aluminum | 46 ± 6 | 4% | 3.3 ± 0.5 |
| | Titanium | 46 ± 6 | 2% | 3.3 ± 0.5 |
| | Copper | 45 ± 6 | 6% | 3.5 ± 0.6 |
| | Molybdenum | 45 ± 7 | 5% | 3.6 ± 0.8 |
| | Titanium- | 48 ± 11 | −1% | 3.6 ± 0.4 |
| | Tungsten | | | |
| Copper | Aluminum | 45 ± 5 | 8% | 3.4 ± 0.4 |
| | Titanium | 47 ± 4 | 3% | 3.5 ± 0.5 |
| | Copper | 47 ± 6 | 3% | 3.3 ± 0.4 |
| | Molybdenum | 45 ± 8 | 6% | 3.4 ± 0.5 |
| | Titanium- | 43 ± 8 | 12% | 3.3 ± 0.6 |
| | Tungsten | | | |

### Example 2

One side of a heat spreader was modified by metal electroplating. Heat spreaders made of aluminum and copper and a silicone TIM were used for the purpose of this example. Each sample was a 2×2 inch substrate. For copper electroplating, the heat spreader was made the cathode, and the metal, or copper here, was made the anode. The cathode and anode were connected through an electrical circuit and subjected to a solution containing copper sulfate and hydrochloric acid. For the copper, an electric current of 40 amperes was passed for about 14 minutes. For nickel plating, the anode was made of nickel. For nickel plating, the cathode and anode were again connected through an electrical connection and subjected to a nickel sulfamate and boric acid solution, under an electric current of 26 amperes for about 4 minutes. For gold electroplating, the anode was made of platinum. The cathode and anode were then connected through an electrical connection and subjected to a potassium gold cyanide solution, under an electric current of 3.1 amperes for about 10 minutes. In line filtration, cathodic movement and N₂ flow were used in the processes evaluated. In line filtration was used to eliminate particulates from the solution that may be introduced by the substrates themselves or by the breakdown of anodes, and a carbon filter is periodically used trap organic contaminates. Cathodic movement was used to keep the plating solution moving and increase plated metal uniformity. Also, nitrogen flow is a purge in the bottom of the plating tank, and was used to assist in solution movement and assist in plated metal thickness uniformity. Table 2 gives the thermal resistance of the interface, before the modification of the second side of the heat spreader, and the percentage reduction in the thermal resistance after the modification of the surface by means of metal electroplating.

TABLE 2

| Heat | | Thermal | Reduction in | |
|---|---|---|---|---|
| Spreader | Processing | Resistance | Thermal | BLT |
| Material | Material | (mm²K/W) | Resistance | (mils) |
| Aluminum | Bright Cu | 49 ± 5 | −2% | 4.5 ± 0.3 |
| | Ni/Au Strike Au | 47 ± 4 | 0% | 3.9 ± 0.3 |
| | Ni | 46 ± 5 | 3% | 3.8 ± 0.4 |
| | Matte Cu | 47 ± 9 | 0% | 4.3 ± 0.4 |
| Copper | Bright Cu | 51 ± 4 | −5% | 3.9 ± 0.2 |
| | Ni/Au Strike Au | 49 ± 3 | 0% | 3.8 ± 0.5 |
| | Ni | 48 ± 7 | 0% | 3.3 ± 0.5 |
| | Matte Cu | 47 ± 4 | 3% | 3.4 ± 0.3 |

### Example 3

One side of a heat spreader was deliberately modified by surface etching. Heat spreaders made of aluminum and copper were used for the Example, and a TIM, commercially available as SilCool LTR3291 from General Electric Co. was also employed. Various chemicals such as, sulfuric acid, phosphoric acid, TFT, ferric chloride, nitric acid, and hydrochloric acid were used in varying concentrations as etching agents. The material to be etched was immersed in the solution for a time varying in a range from about 2 minutes to about 5 minutes to obtain etching.

TABLE 3

| | Processing | Thermal | Reduction in | |
|---|---|---|---|---|
| Heat Spreader | material | Resistance | Thermal | BLT |
| Material | (% in solution) | (mm²K/W) | Resistance | (mils) |
| Aluminum | Sulphuric | 41 ± 6 | 13% | 3.4 ± 0.4 |
| | Acid (25%) | | | |
| | Nitric Acid | 42 ± 7 | 12% | 3.2 ± 0.4 |
| | (25%) | | | |
| | Phosphoric | 42 ± 5 | 11% | 3.3 ± 0.4 |
| | Acid (75%) | | | |
| | TFT (3.3%) | 47 ± 6 | 1% | 3.8 ± 0.4 |
| | Ferric | 105 ± 14 | −121% | 4.7 ± 0.6 |
| | Chloride | | | |
| | (10%) | | | |
| | Hydrochloric | 63 ± 11 | −34% | 4.2 ± 0.3 |
| | Acid (25%) | | | |
| Copper | Sulphuric | 50 ± 7 | −3% | 2.9 ± 0.5 |
| | Acid (25%) | | | |
| | Nitric Acid | 51 ± 8 | −6% | 3.3 ± 0.8 |
| | (25%) | | | |
| | Phosphoric | 51 ± 4 | −6% | 3.1 ± 0.3 |
| | Acid (75%) | | | |
| | TFT (3.3%) | 47 ± 9 | 3% | 2.7 ± 0.8 |
| | Ferric | 45 ± 6 | 6% | 3.1 ± 0.4 |
| | Chloride | | | |
| | (10%) | | | |
| | Hydrochloric | 52 ± 7 | −8% | 3.2 ± 0.6 |
| | Acid (25%) | | | |

### Example 4

One side of a heat spreader was deliberately modified by surface reactive ion etch. Heat spreaders made of aluminum and copper were used for the purpose, and a silicone TIM was employed. Reactive Ion Etching (RIE) was used on aluminum and copper substrate materials to remove residual organic materials, remove native oxides, and to impart ion bombardment. In this study an Anelva parallel plate etch system was used (powered bottom electrode, quartz electrode cover). A process utilizing oxygen and argon was used to treat the samples. Parameters that can be controlled in the RIE process include power, pressure, and etch time. Incorporating Argon into the etch chemistry increases the ion bombardment and makes a more aggressive etch.

TABLE 4

| Heat | | Thermal | Reduction | |
|---|---|---|---|---|
| Spreader | | Resistance | in Thermal | |
| Material | Processing | (mm²K/W) | Resistance | BLT (mils) |
| Al | RIE | 48 ± 6 | −1% | 4.1 ± 0.4 |
| Cu | RIE | 47 ± 8 | 2% | 3.2 ± 0.5 |

### Example 5

One side of a heat spreader was modified by mechanical roughening. Grinding and bead blast were the two methods used to modify the surface by means of mechanical roughening. Heat spreaders made of aluminum and copper were used for this Example, and a silicone TIM was employed.

TABLE 5

| Heat | | Thermal | Reduction | |
|---|---|---|---|---|
| Spreader | | Resistance | in Thermal | |
| Material | Processing | (mm²K/W) | Resistance | BLT (mils) |
| Aluminum | Bead Blast | 50 ± 9 | −6% | 4.3 ± 0.4 |
| | Grinding | 38 ± 4 | 20% | 2.7 ± 0.2 |
| Copper | Grinding | 49 ± 10 | −1% | 2.9 ± 0.7 |
| | Bead Blast | 49 ± 6 | −1% | 4.0 ± 0.8 |

### Example 6

One side of a die was modified by using metal sputtering. Metal sputtering on the die was done in a similar way as on the heat spreader in Example 1. A heat spreader made of aluminum, a TIM made of an alumina filled silicone, and a silicon die was used in this Example. Thermal resistance was measured for the assemblies after applying a pressure of 10 psi. The Al—Cr heat spreader and titanium-tungsten sputtered silicon die showed a significant reduction in BLT and consequently an 18% reduction in thermal resistance (from 44 mm²KW to 36 mm²K/W) was observed. Similarly, a combination of titanium-tungsten sputtered aluminum heat spreader and bare silicon die showed a 23% reduction in thermal resistance (from 44 mm²K/W to 34 mm²K/W). By applying the TIM between a titanium-tungsten sputtered aluminum heat spreader and titanium-tungsten sputtered silicon die there was no additional reduction in BLT or thermal resistance (34 mm²K/W) as compared to having only one modified surface. On increasing the pressure applied on the assembly to 20 psi, there was a slight reduction in the thermal resistance (32 mm²K/W). In addition to titanium-tungsten, Mo, Al, and Cu were sputtered onto the backside of the silicon die. Table 6 shows thermal resistance for different combinations of modified surfaces of the heat spreader, and the die. While the effect of titanium-tungsten and aluminum sputtered surfaces appears to be a clear effect of reduced BLT, the effect of molybdenum sputtering appears to be a combination of reduced BLT and interfacial thermal resistances.

TABLE 6

| Metal Sputtered | | | Thermal | Reduction in | |
|---|---|---|---|---|---|
| on Al Heat | Silicon Die | | Resistance | Thermal | BLT |
| Spreader | Material | Pressure (psi) | (mm²K/W) | Resistance | (mils) |
| Gold Chromate | Bare | 10 | 44 ± 4 | — | 2.3 ± 0.3 |
| Titanium-tungsten | Bare | 10 | 34 ± 2 | 22.7% | 1.8 ± 0.1 |
| Gold Chromate | Titanium- | 10 | 36 ± 3 | 18.2% | 1.3 ± 0.2 |
| | tungsten | | | | |
| Titanium-tungsten | Titanium- | 10 | 34 ± 2 | 22.7% | 1.6 ± 0.1 |
| | tungsten | | | | |
| Gold Chromate | Titanium- | 10 | 37 ± 5 | 16% | 1.5 ± 0.3 |
| | tungsten | | | | |
| Gold Chromate | Molybdenum | 10 | 35 ± 2 | 20% | 2.0 ± 0.1 |
| Gold Chromate | Aluminum | 10 | 36 ± 5 | 18% | 1.5 ± 0.3 |
| Gold Chromate | Copper | 10 | 43 ± 7 | 2% | 2.2 ± 0.4 |
| Gold Chromate | Bare | 20 | 35 ± 5 | — | 1.6 ± 0.4 |
| Ti—W | Mo | 20 | 32 ± 2 | 8.6% | 2.0 ± 0.1 |
| Titanium-tungsten | Titanium- | 20 | 32 ± 1 | 8.6% | 1.4 ± 0.1 |
| | tungsten | | | | |

### Example 7

One side of a heat spreader was modified using an adhesion promoter, Silquest®, commercially available from General Electric Co. The heat spreader was soaked in a solution of the adhesion promoter in toluene for a period of about 10 minutes. Volume percentages of adhesion promoter in toluene were varied from about 5 volume percent to about 20 volume percent. The heat spreader was then baked in an oven at 125° C. for about 1 hour. This resulted in a coating of the adhesion promoter on the heat spreader. Table 7 shows the thermal resistance of a copper heat spreader with adhesion promoter.

TABLE 7

| Heat | | Thermal | Reduction in | |
|---|---|---|---|---|
| Spreader | | Resistance | Thermal | |
| Metal | Finish | (mm\hat{ }2K/W) | Resistance | BLT (mils) |
| Al | Cr (Control) | 50 | — | 3.2 |
| Al | Silquest ® A-186 | 45 | 10.0% | 3.2 |
| Al | Silquest ® A-187 | 42 | 16.0% | 3.1 |
| Cu | Ni (Control) | 43 | — | 3.2 |
| Cu | Silquest ® A-186 | 38 | 11.6% | 2.8 |
| Cu | Silquest ® A-187 | 38 | 11.6% | 3.2 |

While the invention has been illustrated and described in typical embodiments, it is not intended to be limited to the details shown, since various modifications and substitutions can be made without departing in any way from the spirit of the present invention. As such, further modifications and equivalents of the invention herein disclosed may occur to persons skilled in the art using no more than routine experimentation, and all such modifications and equivalents are believed to be within the spirit and scope of the invention as defined by the following claims.

1. A thermal resistance network comprising a heat dissipating unit, a die, and at least one thermal interface material located between the heat dissipating unit and the die, wherein at least one of said heat dissipating unit and said die has a deliberately modified surface.

2. The thermal resistance network according to claim 1, wherein said deliberately modified surface is a mechanically modified surface, modified by a method selected from the group consisting of addition of adhesion layers, application of adhesion promoters, mechanical roughening, patterning, and combinations thereof.

3. The thermal resistance network according to claim 2, wherein the addition of adhesion layers is provided by at least one of, metal sputtering and metal electroplating.

4. The thermal resistance network according to claim 3, wherein the metal sputtering deposits a material selected from the group consisting of titanium, molybdenum, tungsten, copper, aluminium, and combinations thereof.

5. The thermal resistance network according to claim 3, wherein the metal electroplating deposits a material selected from the group consisting copper, nickel, gold, silver and combinations thereof.

6. The thermal resistance network according to claim 2, wherein the deliberately modified surface is modified by application of at least one adhesion promoter selected from the group consisting of alkoxysilanes, titanates, and mixtures and combinations thereof.

7. The thermal resistance network according to claim 2, wherein mechanical roughening is provided by at least one of grinding and bead blast.

8. The thermal resistance network according to claim 2, wherein patterning is provided by at least one selected from the group consisting of milling, stamping, and laser patterning.

9. The thermal resistance network according to claim 1, wherein said deliberately modified surface is a chemically modified surface, modified by a method selected from the group consisting of surface etching and reactive ion etch.

10. The thermal resistance network according to claim 9, wherein the surface etching is provided by a chemical reagent selected from the group consisting of hydrochloric acid, nitric acid, sulfuric acid, phosphoric acid, TFT, ferric chloride, and combinations thereof.

11. The thermal resistance network according to claim 1 wherein said heat spreader is formed from a material selected from the group consisting of gold, aluminium, copper, nickel, silver, metal alloys, silicon, ceramics, refractory materials and combinations thereof.

12. The thermal resistance network according to claim 1, wherein the die further comprises an integrated circuit board.

13. A thermal resistance network comprising a heat dissipating unit, having at least one deliberatly modified surface, a heat generating unit having at least one deliberatly modified surface and a thermal interface material deposited between said heat dissipating unit and said heat generating unit.

14. The thermal resistance network of claim 13, wherein each of said deliberately modified surfaces is selected from the group consisting of a mechanically modified surface, a chemically modified surface and an electrically modified surface.

15. The thermal resistance network of claim 13, wherein each of said deliberately modified surfaces is modified by a method selected from the group consisting of addition of adhesion layers, application of adhesion promoters, mechanical roughening, patterning, surface etching, reactive ion etch and combinations thereof.

16. A thermal resistance network comprising a heat sink, a heat spreader having a first side and a second side, a die having a first side and a second side, a first thermal interface material located adjacent said second side of said heat spreader and said first side of said die, and a second thermal interface material located adjacent said first side of said heat spreader and said heat sink, wherein at least one of said first side of heat spreader, said second side of said heat spreader, and said first side of said die has a deliberately modified surface.

17. A method of forming a thermal resistance network comprising the steps of:
providing a heat sink;
providing a heat spreader;
providing a die;
modifying at least one surface of at least one of said heat spreader and said die; and
providing at least one thermal interface material between said heat spreader and said die.

18. The method according to claim 17, wherein the step of modifying at least one surface comprises the steps of mechanical modification selected from the group consisting of addition of adhesion layers, application of adhesion promoter, mechanical roughening, patterning, and combinations thereof.

19. The method according to claim 18, wherein the step of mechanical modification comprises the addition of adhesion layers provided by metal sputtering.

20. The method according to claim 19, wherein the metal sputtering deposits a material selected from the group consisting of titanium, molybdenum, tungsten, copper, aluminium, and combinations thereof.

21. The method according to claim 18, wherein the step of mechanical modification comprises the addition of adhesion layers provided by metal electroplating, wherein the metal electroplating deposits a material selected from the group consisting of at least one of copper, nickel, gold, silver and combinations thereof.

22. The method according to claim 18, wherein the step of mechanical modification comprises mechanical roughening, said mechanical roughening provided by at least one of grinding and bead blast.

23. The method according to claim 18, wherein the step of patterning is provided by at least one selected from the group consisting of milling, stamping, laser patterning, and any combination thereof.

24. The method according to claim 17, wherein the step of modifying at least one surface comprises the step of chemical modification selected from the group consisting of surface etching and reactive ion etch and combinations thereof.

25. The method according to claim 24, wherein the step of chemical modification comprises surface etching, said surface ethcing provided by a chemical reagent selected from the group consisting of hydrochloric acid, nitric acid, sulfuric acid phosphoric acid, TFT, ferric chloride, and combinations thereof.

26. The method according to claim 17, wherein the step of providing a heat spreader further comprises providing a heat spreader formed from a a material selected from the group consisting of gold, aluminium, copper, nickel, metal alloys, silicon, ceramics, refractory materials and combinations thereof.

27. The method according to claim 17, comprising the additional step of provided an integrated circuit board connected to the die on a side opposite of said heat spreader.

28. The method according to claim 18, wherein the step of mechanical modification comprises addition of an adhesion promoter selected from the group consisting of alkoxysilanes, titanates, and mixtures and combinations thereof.

29. A semiconductor device comprising at least one heat dissipating unit, a die, at least one thermal interface material, and a circuit, wherein at least one of the heat spreader and the die has a deliberately modified surface.
